(19) United States
(12) Patent Application Publication
(10) Pub. No.: US 2011/0272567 A1
(43) Pub. Date: Nov. 10, 2011

(54) Throughput Enhancement for Scanned Beam Ion Implanters

(75) Inventors: Edward C. Eisner, Lexington, MA (US); Bo Vanderberg, Gloucester, MA (US)

(73) Assignee: Axcelis Technologies, Inc., Beverly, MA (US)

(21) Appl. No.: 12/774,037

(22) Filed: May 5, 2010

(51) Int. Cl. H01J 37/317; G12B 13/00

(52) U.S. Cl. 250/252.1; 250/492.21; 250/492.3

(57) ABSTRACT

Some aspects of the present disclosure increase throughput beyond what has previously been achievable by changing the scan rate of a scanned ion beam before the entire cross-sectional area of the ion beam extends beyond an edge of a workpiece. In this manner, the techniques disclosed herein help provide greater throughput than what has previously been achievable. In addition, some embodiments can utilize a rectangular (or other non-circularly shaped) scan pattern that allows real-time beam flux measurements to be taken off-wafer during actual implantation. In these embodiments, the workpiece implantation routine can be changed in real-time to account for real-time changes in beam flux. In this manner, the techniques disclosed herein help provide improved throughput and more accurate dosing profiles for workpieces than previously achievable.

### BACKGROUND

In the manufacture of semiconductor devices and other products, ion implantation systems are used to impart dopant elements into workpieces (e.g., semiconductor wafers, display panels, glass substrates). These ion implantation systems are typically referred to as “ion implanters”.

Ion implanters generate a beam of ions that are ultimately injected into the lattice of a workpiece to promote desired functionality thereon. Because many workpieces are circular in shape, some prior implementations have proposed implanting workpieces according to a scan pattern that traces out an approximately circular or elliptical path, depending on the shape of the beam, in the plane of the workpiece. Because such an elliptical scan pattern maps precisely to the geometry of a workpiece and the shape of the beam, it tends to promote high workpiece throughput in that it limits the time needed to implant individual workpieces. However, this implementation suffers from a shortcoming in that it is difficult to measure dynamic changes in beam flux during implantation. Because of this, the actual dosing profiles delivered by implementations using elliptical scan patterns may tend to diverge from a desired dosing profile over time, due to unaccounted for changes in beam flux. Therefore, optimized ion implantation methods are needed that maintain high throughput while at the same time providing feedback that allows the system to account for dynamic changes in beam flux.

### SUMMARY

The present invention overcomes the limitations of the prior art. Consequently, the following presents a simplified summary of the invention in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

Some aspects of the present disclosure increase throughput beyond what has previously been achievable while maintaining the ability to take real-time beam flux measurements by changing the scan rate of a scanned ion beam before the entire cross-sectional area of the ion beam extends beyond an edge of a workpiece. In these embodiments, the workpiece implantation routine can be changed in real-time to account for real-time changes in beam flux. For example, a translational velocity at which the workpiece is translated and/or a scan velocity at which the ion beam is scanned can be adjusted to account for changes in beam flux. In this manner, the techniques disclosed herein help provide improved throughput and more accurate dosing profiles for workpieces than previously achievable.

To the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### DESCRIPTION OF THE DRAWINGS

FIG. 1 is a plan view of an exemplary ion implantation system according to some embodiments.

FIG. 2A-2B are plan views of an implantation path by which ions are implanted into a workpiece, where the implantation path is traced when the workpiece is translated along a first axis while an ion beam is concurrently scanned along second axis perpendicular to the first axis.

FIGS. 3A-3F illustrate an example of how an ion beam may be scanned along a first surface segment of a workpiece.

FIG. 4 is a flow chart of a method according to some embodiments.

FIG. 5 illustrates an example of how a real-time flux values can be measured during implantation of a workpiece.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details.

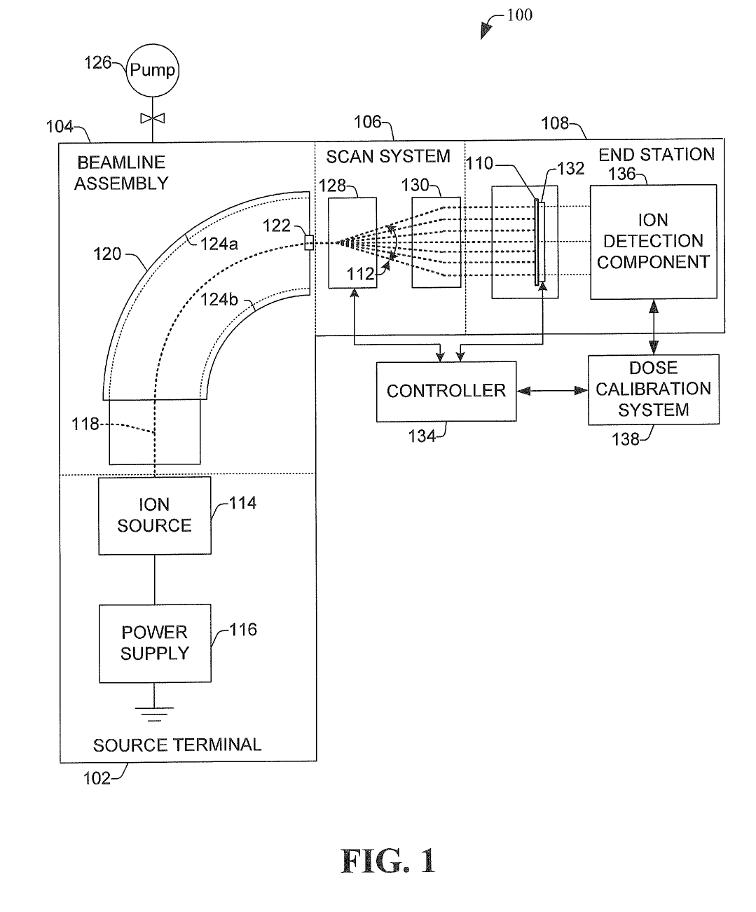

FIG. 1 illustrates an ion implantation system 100 having a source terminal 102, beamline assembly 104, scan system 106, and end station 108, which are collectively arranged so as to inject ions (dopants) into the lattice of a workpiece 110 according to a desired dosing profile. In particular, FIG. 1 illustrates a hybrid-scan ion implantation system 100, wherein the system is operable to translate the workpiece 110 along a first axis while concurrently scanning a beam 112 along a second axis perpendicular to the first axis to achieve the desired doping profile.

During operation, an ion source 114 in the source terminal 102 is coupled to a high voltage power supply 116 to ionize and extract dopant molecules (e.g., dopant gas molecules), thereby forming a pencil ion beam 118.

To steer the pencil beam 118 from the source terminal 102 towards the workpiece 110, the beamline assembly 104 has a mass analyzer 120 in which a dipole magnetic field is established to pass only ions of appropriate charge-to-mass ratio through a resolving aperture 122. Ions having an inappropriate charge-to-mass ratio collide with the sidewalls 124a, 124b; thereby leaving only the ions having the appropriate charge-to-mass ratio to pass into the workpiece 110. The beam line assembly 104 may also include various beam forming and shaping structures extending between the ion source 114 and the end station 108, which maintain the pencil beam 118 in an elongated interior cavity or passageway through which the pencil beam 118 is transported to the workpiece 110. A vacuum pump 126 typically keeps the ion beam transport passageway at vacuum to reduce the probability of ions being deflected from the beam path through collisions with air molecules.

Upon receiving the pencil beam 118, a scanner 128 in the scan system laterally diverts or “scans” the pencil beam back and forth in time (e.g., in a horizontal direction). In some contexts, this type of scanned pencil beam may be referred to as a ribbon beam 112. A parallelizer 130 in the scan system can redirect the ribbon beam 112 so that ions impinging the workpiece 110 continuously strike the face of the workpiece at the same angle of incidence, albeit at different locations in time.

The workpiece 110 may be positioned on a moveable stage 132 which is translated perpendicular to the scanned beam (e.g., in a vertical direction). A controller 134 can control the relative motions imparted to the ribbon beam 112 and workpiece 110 to achieve a desired doping profile on the workpiece 110. To help ensure that the dosing profile delivered to the workpiece follows a desired doping profile and allow the system to account for dynamic changes in beam flux, an ion beam detection component 136 (e.g., one or more faraday cups) and dose calibration system 138 are also included.

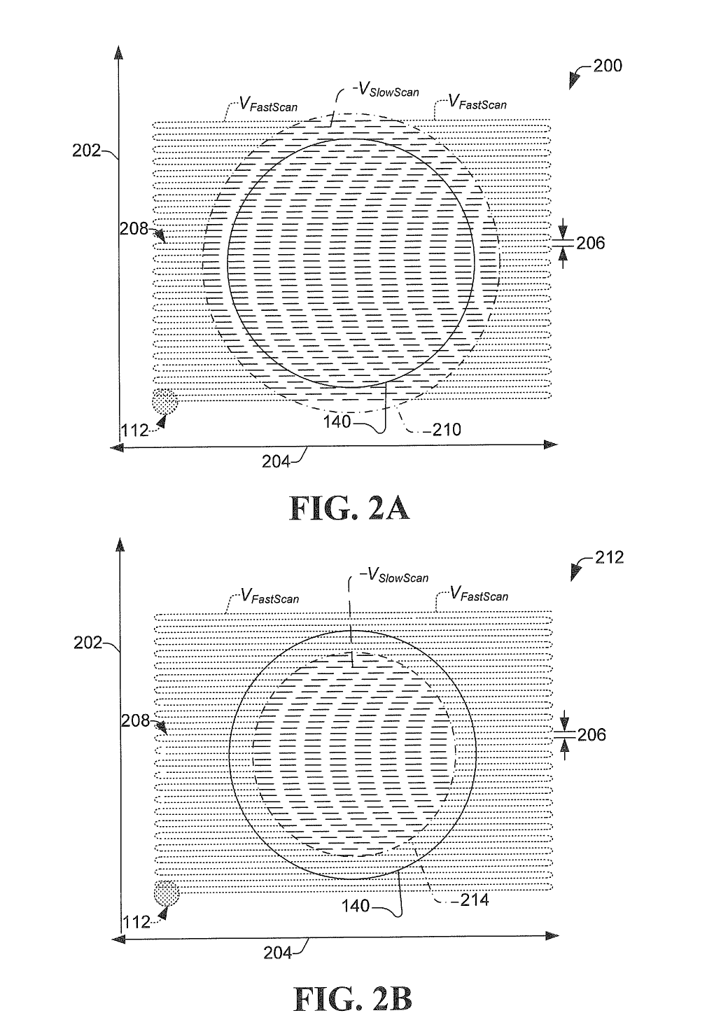

FIGS. 2A and 2B illustrate two examples of how relative motion between the ion beam 112 and the workpiece 110 can be carried out such that the ion beam traces out non-circular implantation paths 200 and 212 in the plane of the workpiece. For the ion beam 112 to trace the illustrated implantation paths 200 and 212, the workpiece 110 is translated along a translation path 202 (e.g., vertical axis) and the ion beam 112 is scanned as a series of scan sweeps along a second axis 204 (e.g., horizontal axis). In the illustrated embodiment, adjacent scan sweeps are parallel to one another because the workpiece 110 is “stepped” from one translation position to the next, causing adjacent scan sweeps to be separated by a distance 206. However, in other embodiments the translational velocity could be continuous, which would cause adjacent scan sweeps to “tilt” relative to one another.

To optimize productivity of the ion implantation system (and limit the time needed to individual implant workpieces), the controller can change the rate at which the ion beam 112 is scanned for a given scan sweep with regards to an outer edge 140 of the workpiece. As the inventors have appreciated, although previous implementations, illustrated in FIG. 2A, have changed between a fast scan rate V_{Fastscan} and slow scan rate V_{slowscan} for a given scan sweep, this change in scan rate occurred at the points 210 when the ion beam 112 passed completely off the workpiece 110.

Therefore, aspects of the present disclosure provide an additional increase in throughput beyond what has previously been achievable by changing the scan rate before the entire cross-sectional area of the ion beam 112 extends beyond an outer edge of the workpiece 140 (shown in FIG. 2B). In other words, the scan rate is changed when only a portion of the cross sectional area of the beam extends beyond the outer edge of the workpiece, illustrated by the circle of transition points 214. In this manner, the techniques disclosed herein help provide greater throughput than what has previously been achievable.

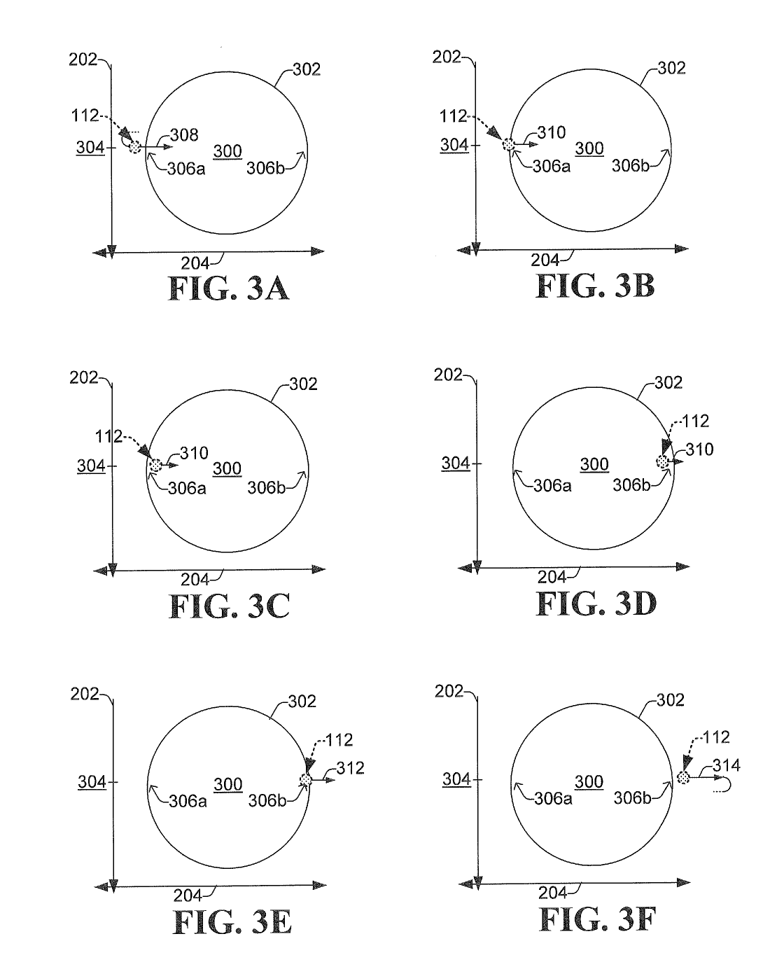

FIGS. 3A-3F generally show how an ion beam scans over two surface segments using different scan velocities on each surface segment. Although FIGS. 3A-3F show only one scan sweep, it will be appreciated that the concepts described with regards to this scan sweep are applicable to any and/or all scan sweeps in an implantation scan path.

In FIG. 3A, a workpiece 300 having an outer edge 302 is positioned at a first translation position 304 with respect to an ion beam 112. For the first translation position 304, a first pair of points 306a, 306b corresponds to the outer edge 302, wherein a first surface segment of the workpiece extends between the first pair of points 306a, 306b. The ion beam 112 starts at an off-workpiece position located beyond the workpiece outer edge 302 and outside of the first pair of points 306a, 306b. The ion beam 112 is then scanned at a first scan rate until it reaches the first surface segment, where the first scan rate has a relatively high velocity as indicated by velocity vector 308. In this manner, the first scan rate helps to minimize “down time” off-workpiece and helps to increase workpiece throughput.

The ion beam 112 can be scanned continuously at the first scan rate until a portion (from all to none) of the cross-sectional area of the ion beam impinges on the workpiece 300, as shown in FIG. 3B. Thus, when a first part of the ion beam is off-workpiece while a second part of the ion beam is on-workpiece (e.g., as shown in FIG. 3B), the ion beam 112 starts to decelerate to a second scan rate. The second scan rate has an instantaneous velocity vector 310 that is less than the first scan rate. In one embodiment, the decrease in velocity occurs when about 33% of the instantaneous beam current impinges on the workpiece. In other words, the change in scan velocity can occur when about 66% of the instantaneous beam current is off-workpiece.

In FIGS. 3C-3D, the ion beam 112 continues to scan at the second scan rate (indicated by velocity vector 310) across the surface segment of the workpiece 110 at the first translation position 304. The second scan rate is less than the first scan rate, as indicated by velocity vector 310. Often, the second scan rate is a nearly constant velocity for a given scan sweep, however the second scan rate can vary along a given scan sweep, for example to improve dose uniformity or to match a non-uniform dose profile, and/or can be different for different scan sweeps depending on the implementation.

In FIG. 3E, the ion beam 112 accelerates from the second scan rate to the first scan rate (as indicated by instantaneous velocity vector 312) before the entire cross-sectional area of the ion beam extends beyond the workpiece boundary. Again, this increase in scan rate while a fraction of the ion beam is still on-workpiece is an improvement over prior art approaches in that it increases throughput by decreasing the amount of time needed to implant individual workpieces. In one embodiment, this increase in velocity occurs when about 33% of the instantaneous beam current impinges on the workpiece.

Finally, in FIG. 3F, the entire cross-sectional area of the ion beam 112 extends past the workpiece outer edge 302 and the ion beam is scanned at the first scan rate. Again, the first scan rate is faster than the second scan rate as indicated by velocity vector 314, thereby limiting the time needed for off-workpiece scanning and helping to promote good throughput. As previously mentioned, other scan sweeps could be carried out in a similar manner until the workpiece receives the desired doping profile.

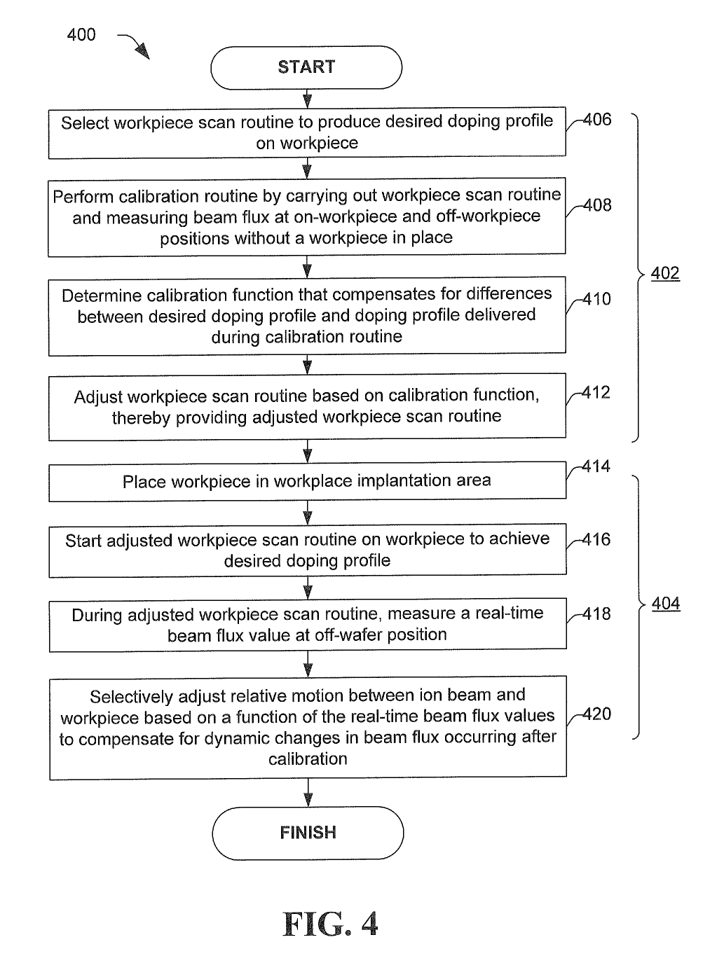

FIG. 4 shows a method 400 in flow chart format in accordance with some aspects of this disclosure. Although this method is illustrated and described below as a series of acts or events, the present disclosure is not limited by the illustrated ordering of such acts or events. For example, some acts may occur in different orders and/or concurrently with other acts or events apart from those illustrated and/or described herein. In addition, not all illustrated acts are required. Further, one or more of the acts depicted herein may be carried out in one or more separate acts or phases.

The method 400 is generally broken down into a calibration routine 402, which is performed without a workpiece in place, and an implantation routine 404 during which a workpiece is actually implanted. Although implantation is only shown for a single workpiece in the illustrated implantation routine 404, one of ordinary skill in the art will appreciate that one or more workpieces can be implanted in a serial manner or in a batch manner, depending on the implementation. The implantation routine 404 may utilize the previously discussed variable scan velocities for a given scan sweep (see e.g., FIGS. 3A-3F), and can also take real-time beam flux measurements during implantation and adjust the scan rate of the ion beam and/or the translational velocity of the workpiece to account for dynamic beam flux variations, as described in more detail below.

Calibration begins at 406 when a workpiece scan routine is selected from a number of possible such routines. The scan routine is selected based on a desired doping profile to be produced on a workpiece. For example, the desired doping profile could be uniform over the whole wafer, or it could have different doses in each of 2 halves of the wafer.

At 408, the method starts the selected workpiece scan routine without a workpiece in place. The workpiece scan routine exhibits relative motion between the ion beam and the workpiece implantation area. The scan routine can exhibit a fast ion beam scan velocity when the ion beam is at an off-workpiece position and when a fraction of the beam is at an on-wafer position, and can exhibit a slow ion beam scan velocity when the ion beam is at the remainder of the on-workpiece positions. As previously discussed with regards to FIGS. 3A-3F, this differing scan velocity helps to optimize workpiece throughput for the ion implantation system. During the workpiece scan routine, a number of beam flux values are measured at on-workpiece positions and off-workpiece positions. For example, an on-workpiece position could correspond to a position corresponding to the center of the workpiece (even though a workpiece is not presently in place during calibration), and an off-workpiece position could correspond to a position beyond an outer edge of the workpiece.

At 410, based on the measured beam flux values, the method determines a calibration function that compensates for differences between the desired doping profile and the doping profile delivered during the calibration routine.

At 412, the method adjusts the selected workpiece scan routine based on the calibration function. Typically, this adjustment can include changing the scan velocity at which the ion beam is translated over one or more sweep scans, and/or can include changing the translational velocity or a distance between one sweep scan and the next.

At 414, a workpiece is placed in the workpiece implantation area (e.g., on movable stage 132 in FIG. 1).

At 416, the method carries out the adjusted workpiece scan routine on the workpiece to achieve the desired doping profile. Because the relative motion of the ion beam and workpiece has been adjusted to account for differences between the desired doping profile and doping profile delivered according to the calibration function, the method 400 allows an ion implanter to provide extremely reliable dosing profiles over a large number of workpieces.

In addition, at 418 during the adjusted workpiece scan routine, the method measures at least one real-time beam flux value at respective off-wafer positions. Typically, the real-time beam flux is measured with one or more current measuring devices (e.g., faraday cups) that are arranged in off-workpiece positions during implantation.

At 420, the method tunes the relative motion of the adjusted workpiece scan routine based on a function of the real-time beam flux value. For example, the measured pressure in the beamline may be used to adjust the measured beam flux value to compensate for photoresist outgassing. If the adjusted real-time beam flux during implantation is greater than a corresponding beam flux value measured during calibration, the method may increase the velocity at which the workpiece is translated to help offset the increased beam flux presently being experienced. Conversely, if the real-time beam flux during implantation is less than a corresponding beam flux value measured during calibration, the method may slow down the velocity at which the workpiece is translated to help offset the decreased beam flux presently being experienced. In this way, the techniques described herein help to deliver extremely accurate dosing profiles to workpieces, even in the event of unexpected and dynamically varying beam flux conditions.

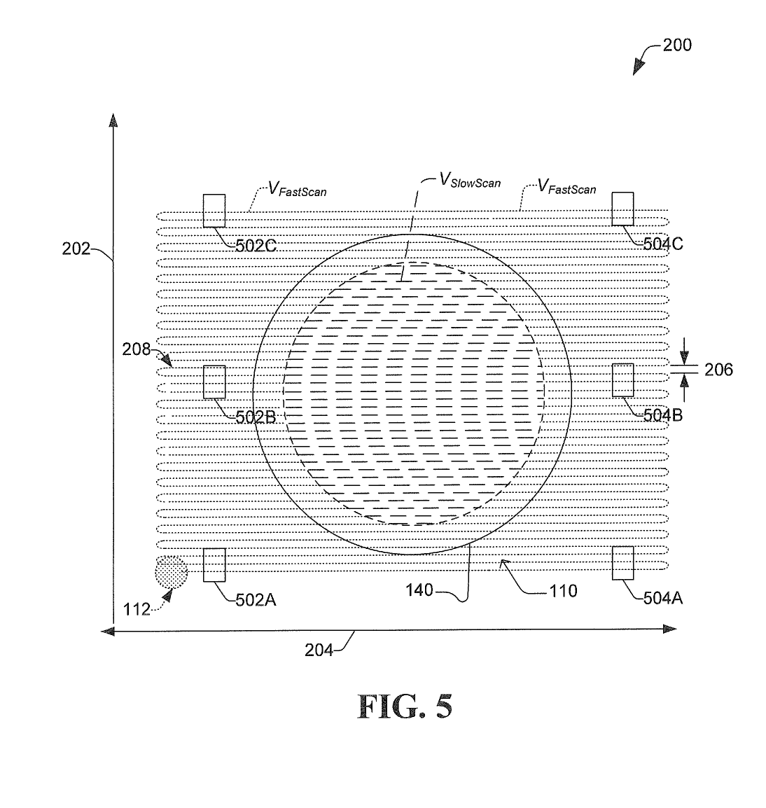

FIG. 5 shows one example of how current measuring devices 502, 504 can be positioned to take real-time beam measurement values as the ion beam is traced along the scan path. As shown, the current measuring devices 502, 504, are often positioned beyond an edge of the workpiece 110 (workpiece boundary) along a given scan sweep. The current measuring devices are often fixed on the second axis 204 in the plane of the scanned ion beam, such that they can measure ion beam flux for each current sweep. Thus, 502A, 504A, represent current measuring devices during a first time interval when the beam is scanned along the bottom of workpiece 110. 502B, 504B represent current measuring devices at a second time interval when the beam is scanned along the middle of the workpiece; and 502C, 504C represent current measuring devices at a third time interval when the beam is scanned along the top of the workpiece.

Although the subject matter has been described in language specific to structural features and/or methodological acts, it is to be understood that the subject matter defined in the appended claims is not necessarily limited to the specific features or acts described above. For example, although an ion implantation system 100 was described above where the ion beam was scanned in a horizontal manner and the workpiece was translated in a vertical manner, relative motion between the ion beam and workpiece can be carried out in other manners. For example, the workpiece could be fixedly mounted with respect to the ion implantation system and the ion beam could be scanned in a horizontal and vertical manner to trace out a desired implantation path. Conversely, the ion beam could be fixed with respect to the ion implantation system and the workpiece could be horizontally and vertically moved to trace out the desired implantation path. Other configurations are also possible, and all such scanned or non-scanned ion beams are contemplated as falling within the scope of the present invention.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements and/or resources), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application. In addition, the articles “a” and “an” as used in this application and the appended claims are to be construed to mean “one or more”.

Furthermore, to the extent that the terms “includes”, “having”, “has”, “with”, or variants thereof are used in either the detailed description or the claims, such terms are intended to be inclusive in a manner similar to the term “comprising.”

What is claimed is:

1. A method for performing ion implantation on a workpiece, wherein the workpiece has a surface terminating at an outer edge, the method comprising:
scanning an ion beam across the surface of the workpiece at a first scan rate when a cross-sectional area of the ion beam is entirely impingent on the surface of the workpiece; and
increasing the first scan rate to a second rate when a portion of the cross sectional area of the beam extends beyond the outer edge of the workpiece, where the portion is less than the entire cross sectional area of the ion beam.

2. The method of claim 1, wherein the portion of the cross sectional area corresponds to approximately sixty-six percent of instantaneous beam current provided by the ion beam.

3. The method of claim 1, further comprising:
continuing to scan the ion beam at the second rate until the entire cross-sectional area of the ion beam has extended beyond the outer edge of the workpiece;
scanning the ion beam back towards outer edge of the workpiece at the second scan rate; and
decreasing the second scan rate to the first scan rate when a second portion of the cross sectional area of the beam impinges on the surface of the workpiece, wherein the second portion less than the entire cross sectional area of the ion beam.

4. The method of claim 3, wherein the second portion of the cross sectional area corresponds to approximately thirty-three percent of instantaneous beam current provided by the ion beam.

5. The method of claim 1, further comprising:
measuring a real-time beam flux value at an off-workpiece position located beyond the edge of the workpiece; and
adjusting relative motion of the workpiece and the ion beam based on a function of the real-time beam flux value.

6. The method of claim 5, wherein adjusting the relative motion of the workpiece and the ion beam is achieved by adjusting a translational velocity at which the workpiece is translated.

7. The method of claim 5, wherein adjusting the relative motion between the workpiece and the ion beam is achieved by cooperatively adjusting both a translational velocity at which the workpiece is translated and a rate at which the ion beam is scanned.

8. A method of ion implantation, comprising:
positioning a workpiece having an outer edge at a first translation position, wherein the first translation position lies on a translation path;
determining a first pair of points corresponding to the outer edge of the workpiece for the first translation position, wherein a first surface segment of the workpiece extends between the first pair of points;
scanning an ion beam over the first surface segment according to a first scan rate when a cross sectional area of the ion beam falls entirely on the first surface segment between the first pair of points; and
increasing the scan rate of the ion beam to a second scan rate when a first portion of the cross sectional area of the ion beam falls outside of the first pair of points, wherein the first portion is less than the entire cross sectional area of the ion beam.

9. The method of claim 8, wherein the first portion of the cross-sectional area of the ion beam corresponds to approximately sixty-six percent of instantaneous beam current of the ion beam.

10. The method of claim 8, further comprising:
performing a calibration prior to positioning the workpiece on the translation path;
measuring a first set of beam flux values at a first position outside of the first pair of points during the calibration;
measuring a second set of beam flux values at a second position between the first pair of points during the calibration;
based on first and second sets of beam flux values, determining an expected doping profile delivered during the calibration;
analyzing differences, if any, between a desired doping profile and the expected doping profile; and
providing a calibration function to compensate for the differences, if any.

11. The method of claim 10, further comprising:
setting the first scan rate based on the calibration function.

12. The method of claim 10, further comprising:
setting the second scan rate based on the calibration function.

13. The method of claim 10, wherein the workpiece is translated between the first translation position and a second translation position according to a translation velocity; and
wherein the translation velocity is set based on the calibration function.

14. The method of claim 8, further comprising:
during implantation of the workpiece, measuring a real-time beam flux value at an off-workpiece position located beyond the edge of the workpiece.

15. The method of claim 14, further comprising:
adjusting the first scan rate based on a function of the real-time beam flux value.

16. The method of claim 14, further comprising:
adjusting the second scan rate based on a function of the real-time beam flux value.

17. The method of claim 8, further comprising:
adjusting a translational velocity at which the workpiece is translated with respect to the ion beam based on a function of the real-time beam flux value.

18. An ion implantation system, comprising:
an ion source configured to provide an ion beam along a beam path;
a beamline assembly configured to selectively direct a desired species from the ion beam along the beam path towards a workpiece positioned on a movable stage;
a stage controller configured to translate the moveable stage at a first rate along a first axis at least substantially perpendicular to the beam path;
a scanner configured to divert the ion beam from the beam path along a second axis at least substantially perpendicular to both the beam path and the first axis, where the scanner is configured to divert the ion beam at a first scan rate when the ion beam is on-workpiece and moving towards an edge of the workpiece, and further configured to increase the scan rate of the ion beam before an entire cross-sectional area of the ion beam extends beyond the edge of the workpiece.

19. The ion implantation system of claim 18, where the scanner is further configured to:
after an entire cross-sectional area of the ion beam extends beyond the edge of the workpiece, scan the ion beam at a second scan rate that is greater than the first scan rate.

20. The ion implantation system of claim 18, further comprising:
a calibration system configured to carry out a calibration routine without the workpiece in the beam path and determine a calibration function that facilitates compensation of dynamic changes in beam flux.

21. The ion implantation system of claim 18, where the stage controller and scanner collectively trace out an implantation path in the plane of the workpiece that differs from a geometry of the workpiece in the plane.
